(19) United States
(12) Patent Application Publication
(10) Pub. No.: US 2012/0280213 A1
(43) Pub. Date: Nov. 8, 2012

(54) Method of Fabricating Thin Film Transistor and Top-gate Type Thin Film Transistor

(75) Inventors: Chie Gau, Tainan City (TW); Shiuan-Hua Shiau, Tainan City (TW); Bai-Sheng Cheng, Tainan City (TW)

(73) Assignee: National Cheng Kung University, Tainan City (TW)

(21) Appl. No.: 13/463,856

(22) Filed: May 4, 2012

(30) Foreign Application Priority Data
May 4, 2011 (TW) 100115551

(51) Int. Cl. H01L 29/772; H01L 21/336; B82Y 99/00; B82Y 40/00

(52) U.S. Cl. 257/29; 438/197; 977/750; 257/E21.411; 257/E29.242

(57) ABSTRACT

A method of fabricating a thin film transistor (TFT) and a top-gate type thin film transistor are disclosed, the method of fabricating a TFT of the present invention comprises steps: (A) providing a substrate; (B) forming a source electrode, a drain electrode, and SWCNT (singled-walled carbon nanotubes) layer on the substrate, in which the source electrode and the drain electrode are spaced in a distance and the SWCNT layer is located between the source electrode and the drain electrode; (C) forming a gate oxide layer on the SWCNT layer; (D) annealing the gate oxide layer with oxygen or nitrogen gas; and (E) forming a gate electrode on the gate oxide layer; wherein the temperature used in the step (D) for annealing is a 500° C. to 600° C.

### BACKGROUND OF THE INVENTION

1. Field of the Invention

The present invention relates to a top gate thin film transistor and a method for fabricating the same. More particularly, the invention relates to a fabrication method subjecting single-walled carbon nanotubes in channeling layers.

2. Description of Related Art

Waves of study for synthesis and application of carbon nanotube found its root since its discovery in 1993. Of particular note with regard to its technology development is the Maruyama research team of Tokyo University of Japan, it was the first one to utilize alcohol catalytic chemical vapor deposition (ACCVD) to produce high-purity single-walled carbon nanotube. The nanotube resulting from this treatment process enjoys excellent electrical conductivity, simple manufacturing method, interpretability with photolithography and others, all of which has long drawn heavy attention from the scholarly community.

Alternatively, in response to the current state of technology development in electrical transistor and its size miniaturization, there has been a growing demand for novel materials as a sustainable replacement for future use. References have suggested that effort by a research team has studied the making of p-type single-walled carbon nanotube matrix transistor by splintering carbon tubes, such transistor features a on-off current ratio up to 10⁶ fold and a field-effect carrier mobility up to 7 cm²/Vs.

In most cases for conventional operation of carbon nanotube, the majority of the carbon nanotube transistors are set up to show p-type characteristics. This is generally attributed to as a result of the carbon nanotube's combining with oxygen upon exposure to an atmospheric environment. It is also well known to one skilled in the art to use treatments including annealing and potassium-doping as a means to effectively modulate the n-type or p-type impurity of an electrical transistor.

Meanwhile, the H.Dai research team has put forth a theory that parametric adjustment of the nanotube's radius, bandgap size, and work function of different metals and carbon tubes has a lead to change the properties of an electrical transistor. The IBM research team has discovered that carbon nanotube and the contact surface of an electrode are highly sensitive as subject to work function, where the absoprting oxygen at the contact surface can result in an increase in work function at the metal's contact surface, which, although still permits negative voltage electrons free passage, the opposite electron hole of the negative voltage electrons would turn to be cut off because of energy barrier overkill.

Conventional research trend has been suggestive that the research priority has been focusing primarily on single carbon nanotube, and less on carbon nanotube matrix transistor. Since the carbon nanotube thin film promises simple manufacturing process, compatibility with integrated circuit manufacturing, upward scalability to large surface area, call of a novel mainstream material for use in nano-scale transistor is foreseeable in the near future.

It has as in fact been suggested by people having skill in the art that semiconductive single-walled carbon nanotube can turn to exhibit n-type semiconductor property if adsorbing nitrogen onto its surface, and exhibit p-type property if adsorbing oxygen onto its surface. However, we have found through our attempt that directly subjecting nitrogen or oxygen gas to carbon nanotube and conducting annealing at high temperature thereafter will significantly lower the substrate property including field-effect mobility and transconductance, which, as shown by Raman analysis, the G/D ratio hereof sees a decrease as well. In other words, annealing directly on carbon tube thin film would cause structural damage to the carbon tube thin film, thereby making it impossible to directly apply this treatment to the manufacturing of thin film transistor.

As such, this technology field demands a method for fabricating a novel single-walled carbon nanotube based thin film transistor, wherein the method can convert the ambiduality of a single-walled carbon nanotube into single-polarity, and can make single-walled carbon nanotube for passage layer in thin film transistor.

### SUMMARY OF THE INVENTION

Wherefore, it is an objective of the present invention to provide a manufacturing method for thin film transistor, which comprises the steps of: (A) providing a substrate; (B) forming a source electrode, a drain electrode, and a single-walled carbon nanotube layer, wherein the source electrode and the drain electrode are disposed separately from each other, and the single-walled carbon nanotube layer is inserted between the source electrode and the drain electrode; (C) forming an oxide gate electrode on a surface of the single-walled carbon nanotube layer; wherein, (D) annealing a surface of the oxide gate electrode with an element selected from oxygen and nitrogen on a temperature at between about 500° C. to about 600° C.

The present invention involves using nitrogen and oxygen annealing to conduct annealing treatment after forming oxide gate electrode on the surface of single-walled carbon nanotube, wherein the ambiduality of the singled-walled nanotube is converted to single-polarity by adjusting annealing parameters for use as a transistor part. More specifically, an advantage suggested by the present invention is realized by first covering an oxide gate electrode (for example, HfOₓ), followed by an annealing treatment, which altogether aims firstly to increase dielectric constant of the oxide gate electrode, while secondly to allow nitrogen or oxygen gas to diffuse through the oxide gate electrode to reach the nanotube during the annealing treatment.

The setup to allow direct entry of nitrogen and oxygen gas into carbon nanotube thin film as suggested by some prior arts has been known to cause the property of device parts to decrease and drop in G/D ratio, which therefore disables making of thin film transistor to have desirable property for its parts. Conversely, the present invention can not only maintain a G/D ratio value of a carbon nanotube, but also enhances its parts' property (examples include transconductance, on-off current ratio, field-effect carrier mobility etc.), this feature is not possible with the known prior arts.

In an embodiment of the present invention, the preferred material for oxide gate electrode is hafnium oxide (HfOₓ). With the present invention, which in one aspect uses a sputtering technique to deposit hafnium oxide, a part of the single-walled carbon nanotube would exhibit as ambipolar under a non-annealing condition. Furthermore, it is found that the ambipolarity of the transistor part can be effectively managed so as to convert to single-polar transistor after the oxide gate electrode is subject to annealing with different gas and different condition parameters. In addition, the annealing treatment also enhances other properties of the device parts, including transconductance, on-off current ratio, field-effect carrier mobility etc.

The most frequently adopted material for use as oxide gate electrode in nanotube transistor is silicon dioxide (SiO₂) because of its good accessibility and affordability. However, silicon dioxide can only be used in oxide gate electrode, but not also be acted together with other gases in order to notably elevate its dielectric constant. Also when conducting nitrogen or oxygen annealing, these two gases can no longer react with silicon dioxide for any desired effect, and the nitrogen or oxygen atoms will not diffuse to the nanotube. Therefore it is preferable to use hafnium oxide thin film as oxide gate electrode.

In another embodiment of the present invention, the thickness of the oxide gate electrode is preferrably of between about 5 nm to about 30 nm.

In one embodiment of step (D) of the present invention, the oxygen or nitrogen annealing treatment on the oxide gate electrode preferrably lasts for about 30 minutes to about 1 hour.

In another embodiment of step (D) of the present invention, the fluid flow velocity for the oxygen or nitrogen annealing treatment is preferrably set at between about 100 sccm to about 500 sccm. In the case of using high-temperature vacuum chamber tube, the vacuum annealing treatment is controlled to be at about 10 torr, therefore it is not advised to be either too large or too small.

In an embodiment of the present invention with respect to using oxygen or nitrogen or other gases for annealing treatment for the effect on device parts' properties, the speculation is that the two types of gas molecules individually diffuse through the oxide gate electrode at high temperatures to combine with the nanotube, changing the semiconductive properties of the nanotube (i.e. converting to n or p state), which thereby causes changes in device parts' properties.

In another embodiment of step (B) of the present invention, the single-walled carbon nanotube is made by the steps of the following: (B1) placing a plurality of metal-containing nanoparticles into a solvent so as to form a catalyst; (B2) immersing the substrate as prepared in step (A) in the catalyst; (B3) removing the immersed substrate from the catalyst and entering the substrate to a calcinating treatment; and (B4) heating the calcinated substrate, and also providing an alcohol-based growth gas source, thereby forming a plurality of single-walled carbon nanotubes on a surface of the substrate with the alcohol-based growth gas source, wherein the plurality of single-walled carbon nanotubes cross-link with each other to form a net-like structured carbon nanotube layer.

In one aspect of the above step (B4), the alcohol-based growth gas is to be selected from the group consisting of: methanol, ethanol, propan-1-ol, isopropyl alcohol, n-butanol, isobutanol, pentanol, and any combination thereof. In an aspect of the above step (B1), the plurality of metal-containing nanoparticles is selected from the group consisting of cobalt, molybdenum, and any combination thereof. In one aspect of the above step (B4), the substrate is preferrably heated at between about 600° C. to about 900° C. In an aspect of the above step (B3), the substrate is preferrably calcinated at between about 320° C. to about 480° C. In addition, between the above cited step (B3) and step (B4), a further step (B3′) is preferrably added: providing an ammonia to conduct a reduction reaction.

Furthermore in another aspect of the step (B1), the solvent is preferrably selected from the group consisting of ethanol, methanol, propan-1-ol, isopropyl alcohol, n-butanol, isobutanol, pentanol, and any combination thereof. The G/D ratio of the single-walled carbon nanotube layer as described in step (B4), analyzed by Raman scattering spectrum, is preferrably of between 10 and between 25.

In another embodiment of the present invention, the plurality of single-walled carbon nanotube is preferrably formed with an ACCVD platform device.

In one aspect of the above step (B), the single-walled carbon nanotube is preferrably made a passage layer, and the thickness of the single-walled carbon nanotube is preferrably of between about 100 nm to 400 nm.

In one embodiment of the present invention, the oxide gate electrode is preferrably formed by a sputtering method.

In another embodiment of the present invention, the material comprising the substrate is unrestricted, for example, the substrate can be made from glass, quartz, plastics, silicon, etc.

The present invention further provides a top-gate thin film transistor, comprising: a substrate; a source electrode and a drain electrode, wherein the source electrode and the drain electrode are disposed separately from each other on a surface of the substrate; a single-walled carbon nanotube layer, which includes a cross-linked matrix of a plurality of single-walled nanotubes, and the single-walled carbon nanotube is disposed at between the source electrode and the drain electrode, and is disposed at the surface of the substrate; an oxide gate electrode, which is disposed at the surface of the substrate, which covers a portion of the source electrode and a portion of the drain electrode; and a gate electrode, which is disposed over a surface of the oxide gate electrode.

The present invention uses nitrogen and oxygen annealing treatment to form oxide gate electrode over the surface of the single-walled carbon nanotube prior to conducting an annealing treatment, thereby adjusting different annealing parameters to in one aspect convert the ambipolarity of the single-walled carbon nanotube into single polarity, making possible a top-gate thin film transistor part. It is known in the prior arts as a consequence that the device part property will decrease and the G/D ratio will decrease as a result of directly passing nitrogen or oxygen gas through carbon nanotube thin film, and as such it is not possible to a top-gate thin film transistor wherein single-walled carbon nanotube layer is disposed over the source electrode and the drain electrode. On the contrary, the top-gate thin film transistor provided by the present invention can be demonstrated to maintain the G/D ratio of the carbon nanotube, and can further increase the device part property (which, for example, includes transconductance, on-off current ratio, field-effect carrier mobility, etc.), this feature is not possible with the known prior arts.

In an embodiment of the present invention, the oxide gate electrode is preferrably selected from the group consisting of hafnium oxide (HfOₓ), hafnium oxynitride, and any combination thereof.

In another embodiment of the present invention, the G/D ratio of the single-walled carbon nanotube layer as analyzed by Raman scattering spectrum is preferrably of between 10 and between 25.

In yet another embodiment of the present invention, the single-walled carbon nanotube layer is preferrably made a passage layer.

In still another embodiment of the present invention, the thickness of the single-walled carbon nanotube layer is preferrably of between about 100 nm to about 400 nm.

Other objects, advantages, and novel features of the invention will become more apparent from the following detailed description when taken in conjunction with the accompanying drawings.

### BRIEF DESCRIPTION OF THE DRAWINGS

The above and other features and advantages of the present invention will become more apparent with reference to the following detailed description when considered in conjunction with the accompanying drawings in which:

FIGS. 1A through 1D schematically illustrate in process flow representation a preferred embodiment 1 of manufacturing the top gate thin film transistor.

FIG. 2 is a I_{ds} v. V_{gs} curve illustrating component measurement results for top gate thin film transistor prepared by preferred embodiments 1-3 property performance of from the preferred embodiments 1-3 of the current invention and control group 1.

FIG. 3 is a I_{ds}-V_{gs} characteristics curve illustrating component measurement results for top gate thin film transistor prepared by preferred embodiments 4-6 property performance of from the preferred embodiments 4-6 of the current invention and control group 2.

FIG. 4 is a I_{ds}-V_{gs} characteristics curve illustrating component measurement results for top gate thin film transistor prepared without annealing.

FIG. 5 is a I_{ds}-V_{gs} characteristics curve illustrating component measurement results for n-type top gate thin film transistor prepared without annealing.

### DETAILED DESCRIPTION OF THE PREFERRED EMBODIMENT

### Embodiment 1

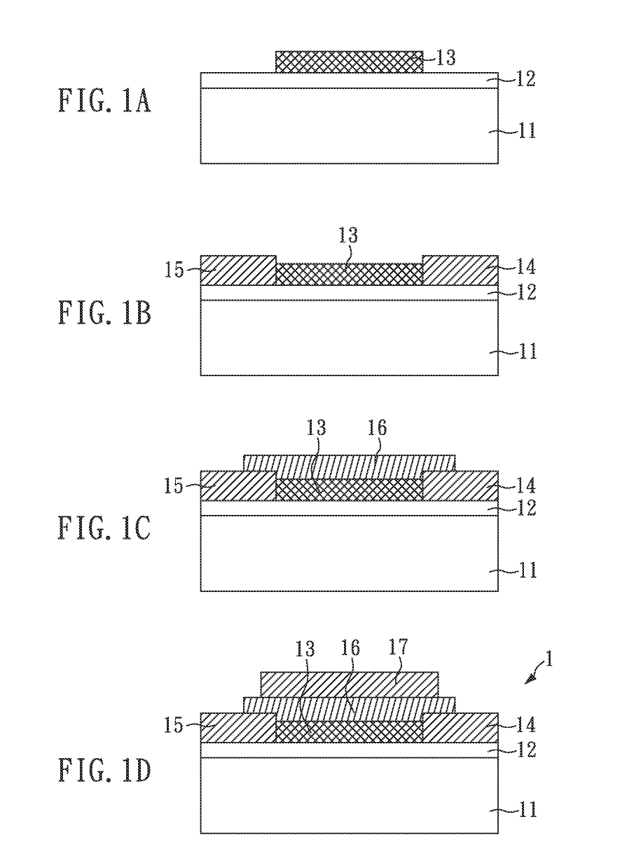

As illustrated in FIG. 1, it is first provided a silicon substrate 11 (step A) comprising a surface having a silicon dioxide layer 12, and on the silicon substrate 11 herein there is a single-walled carbon nanotube thin film 13 of a thickness of about 200 nm as deposited by a ACCVD device. The pattern of the passage region on the single-walled carbon nanotube transistor (step B) is defined by a photolithography technique and an etching technique. Next, as shown in FIG. 1B, a metal electrode layer (20 nm of gold/300 nm of titanium) having a drain electrode 14 and a source electrode 15 is formed by a metal deposition system and a lift-off lithography. Afterwards, a hafnium oxide layer (HfOₓ) 16 deposited to be of about 10 nm by a sputtering device is made an oxide gate electrode of the transistor, as illustrated in FIG. 1C (step C). Afterwards, photolithography and dry etching technique etch the hafnium oxide layer 16 to form a contact hole containing a drain electrode 14 and a source electrode 15 (not known in figures).

The next step involves conducting oxygen annealing on a surface of the hafnium oxide layer 16 for 30 minutes at a tempter of 500° C., a pressure of 10 ton, a flow rate of 100 sccm (step D). Herein, oxygen atom diffuse through the oxide gate electrode to combine with the nanotube at a high operating temperature upon the hafnium oxide layer 16 being oxygen annealed at high temperature, changing the semiconductivity of the nanotube, thereby changing the entire device part's property, and further attributing the single-walled carbon nanotube thin film 13 qualities of a passage layer.

Lastly, the lift-off lithography technique is used once again to deposit metal gate electrode 16 in order to complete the manufacturing process of the device part (step E). The top-gate electrode thin film transistor 1 as embodied in the present invention is made therefrom.

In the present invention, the single-walled carbon nanotube 13 of step B is formed by the following steps: (B1) placing a plurality of metal-containing nanoparticles (as an example herein, cobalt acetate powder and a molybdenum acetate powder are used) into a solvent so as to form a catalyst, as an example herein, the solvent is ethanol, and ratio between the cobalt acetate and molybdenum acetate, and ethanol is [cobalt acetate and molybdenum acetate:ethanol]=0.01 wt %. Next, (B2) the silicon substrate 11 is immersed into the catalyst; making a surface of the silicon substrate 11 adsorbed with the catalyst. Hereinafter, (B3) the immersed substrate 11 is removed from the catalyst and the substrate 11 is entered into a calcinating treatment, where the calcinating temperature is 400° C. Following this step, (B3′) involves providing ammonium gas and argon gas as a means to initiate a reduction reaction through calcinating a surface of the silicon substrate 11. The reduction reaction disclosed herein operates the ammonium gas/argon gas to be at 30/200 sccm, at a temperature of between about 350° C. and 750° C., and at a pressure of about 15-20 torr. The following step (B4) involves heating the calcinated and reduced substrate to be at 750° C., and at the same time providing an alcohol type growth gas source (as an example herein, conditions may include an ethanol of purity of about 99.9% , a pressure of 690 torn a temperature of 50° C.), thereby forming a plurality of single-walled carbon nanotubes on a surface of the substrate (as an example herein, the duration lasts 10 minutes, and an ACCVD device), wherein the plurality of single-walled carbon nanotubes cross-link with each other to form a net-like structured carbon nanotube layer, and the thickness of the net-like structured thin film is of about 200 nm.

Turning now to FIG. 1D, the embodiment presented herein discloses a top-gate thin film transistor 1 comprising a silicon substrate 11, a surface of which has a silicon dioxide layer 2; a source electrode 15 and a drain electrode 14, wherein the source electrode and the drain electrode are disposed separately from each other on the surface of the silicon substrate 11; a single-walled carbon nanotube thin film 13, which comprises plurality of single-walled carbon nanotube having a cross-linked structure, and is disposed over the surface of the silicon substrate 11; an oxide gate electrode having a hafnium oxide layer 16, which is disposed over a surface of the single-walled carbon nanotube thin film 13, and covers over the source electrode 15 and the drain electrode 14; and a gate electrode 17, which is disposed over a surface of the hafnium oxide 16.

### Embodiment 2

An identical method of fabricating a top-gate type thin film transistor as disclosed in embodiment 1 described therein, but the oxygen flow rate of step D for oxygen annealing treatment is 300 sccm, in stead of 100 sccm.

### Embodiment 3

An identical method of fabricating a top-gate type thin film transistor as disclosed in embodiment 1 described therein, but the oxygen flow rate of step D for oxygen annealing treatment is 500 sccm, in stead of 100 sccm, and the duration is 60 minutes, in stead of 30 minutes.

### [Control Group 1]

An identical method of fabricating a top-gate type thin film transistor as disclosed in embodiment 1 described therein, but the step D is precluded, and the oxygen annealing treatment is precluded.

TABLE 1

| P-Type FET | | Field-Effect | |
|---|---|---|---|
| Operation | Transconductance | Mobility | On-off Current |
| Measurement | (μ) | (cm²/Vs) | Ratio |
| Control group 1 | 3.2 | 52.74 | ~10⁵ |
| Oxygen flowing | 5.4 | 96.67 | 10⁵ |
| at 100 sccm, | | | |
| annealing | | | |
| duration for 30 | | | |
| minutes | | | |
| Oxygen flowing | 9.7 | 172.57 | 10⁵~10⁶ |
| at 300 sccm, | | | |
| annealing | | | |
| duration for 30 | | | |
| minutes | | | |
| Oxygen flowing | 10.6 | 189.03 | 10⁶ |
| at 500 sccm, | | | |
| annealing | | | |
| duration for 60 | | | |
| minutes | | | |

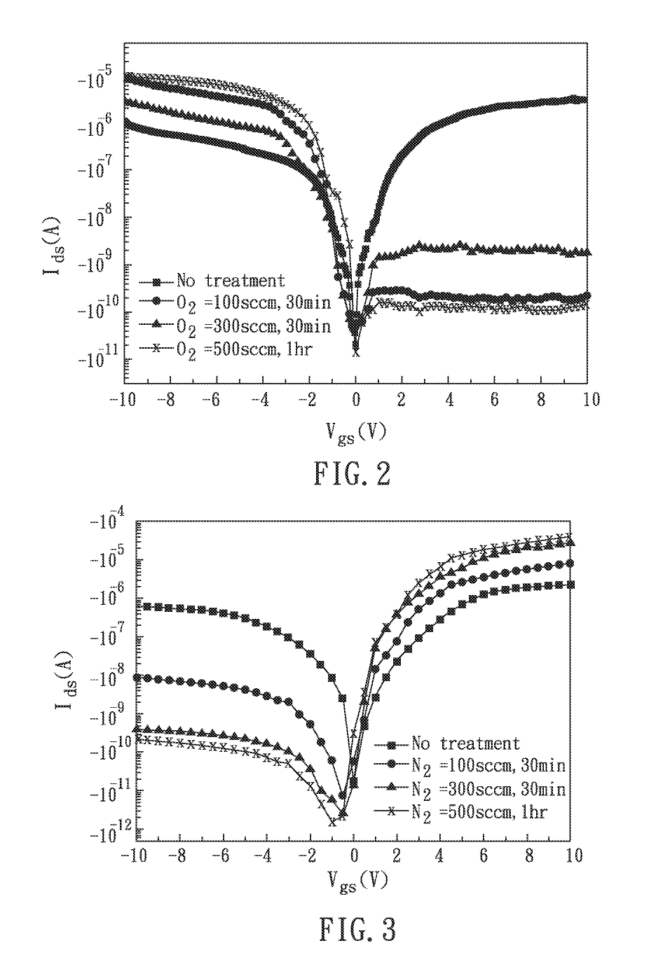

FIG. 2 shows the change in behavior of the transistor part property in response to changes in the hafnium oxide layer with different parametric conditions in oxygen annealing treatment. It can be clearly seen in the Figure that the transistor part converts from the original ambipolar state into p-type single-polar state. In addition to this, when the transistor is undergoing a p-type operation measurement, its transconductance and on-off current ratio, field-effect carrier mobility all clearly show significant upward trend, the calculated value for the results is recorded in Table 1.

### Embodiment 4

An identical method of fabricating a top-gate type thin film transistor as disclosed in embodiment 1 described therein, but the step D involves using nitrogen to conduct annealing treatment, and the used nitrogen flow rate is 100 sccm, and the annealing duration is 30 minutes.

### Embodiment 5

An identical method of fabricating a top-gate type thin film transistor as disclosed in embodiment 4 described therein, but the nitrogen flow rate in step D is 300 sccm, instead of 100 sccm.

### Embodiment 6

An identical method of fabricating a top-gate type thin film transistor as disclosed in embodiment 4 described therein, but the nitrogen flow rate in step D is 500 sccm, instead of 100 sccm, and the duration is 60 minutes, in stead of 30 minutes.

### [Control Group 2]

An identical method of fabricating a top-gate type thin film transistor as disclosed in embodiment 1 described therein, but step D is precluded, and oxygen annealing treatment or nitrogen annealing treatment is precluded.

TABLE 2

| N-Type FET | | Field-Effect | |
|---|---|---|---|
| Operation | Transconductance | Mobility | On-off Current |
| Measurement | (μ) | (cm²/Vs) | Ratio |
| Control group 2 | 4.3 | 67.08 | 10⁵ |
| (no annealing | | | |
| treatment) | | | |
| Embodiment 4 | 7.2 | 112.32 | 10⁵~10⁶ |
| (nitrogen flowing | | | |
| at 100 sccm, | | | |
| annealing | | | |
| duration for 30 | | | |
| minutes) | | | |
| Embodiment 5 | 12.8 | 199.68 | 10⁶~10⁷ |
| (oxygen flowing | | | |
| at 300 sccm, | | | |
| annealing | | | |
| duration for 30 | | | |
| minutes) | | | |
| Embodiment 6 | 13.7 | 213.72 | 10⁷ |
| (oxygen flowing | | | |
| at 500 sccm, | | | |
| annealing | | | |
| duration for 60 | | | |
| minutes) | | | |

FIG. 3 shows the change in behavior of the transistor part property in response to changes in the hafnium oxynitride (HfOₓN_{y}) layer with different parametric conditions in nitrogen annealing treatment. It can be clearly seen in the Figure that the transistor part converts from the original ambipolar state into n-type single-polar state. In addition to this, when the transistor is undergoing a n-type FET operation measurement, its transconductance and on-off current ratio, field-effect carrier mobility all clearly show significant upward trend, the calculated value for the results is recorded in Table 2. A postulation with regard to this result is that at an operating condition of N₂=300 sccm, 550° C. and a duration of 30 minutes, the oxide layer thin film is highly capable to finish a reaction and can form nitrogen-containing thin film. Not only this, a modulated temperature and gas atoms can, through migrating through the oxide layer, impart influence on the contact surface between the metal and the carbon nanotube, making the work function of the contact surface and contact resistivity susceptible to change as induced by annealing, thereby causing the device part property to change.

### [Measurement of Dielectric Constant]

Taking into account of Embodiment 2, Embodiment 5, and the capacity value of the hafnium oxide thin film (measuring frequent at 2 MHz), and combined with the formula, C=∈ᵣ∈ₒ(A/tₒₓ) to calculate the dielectric constant ∈ᵣ gives the following result:

| | Control Group 1 | Control Group 2 | Control Group 5 |
|---|---|---|---|
| Dielectric | 12.08 | 12.73 | 14.19 |
| Constant (εᵣ) | | | |

It is demonstrated that the dielectric constant of the hafnium oxide thin film indeed sees an increase at an annealing condition of using nitrogen or oxygen at a temperature of 550° C., a pressure of 10 ton, a duration of 30 minutes. The level of change in the dielectric constant is the greatest especially after a nitrogen annealing treatment. It is postulated that the original hafnium oxide thin film will become a hafnium oxynitride thin film, and the doped nitrogen atom works out to stimulate the dielectric constant.

### Property Analysis for Single-Walled Carbon Nanotube transistor

### Without annealing Treatment

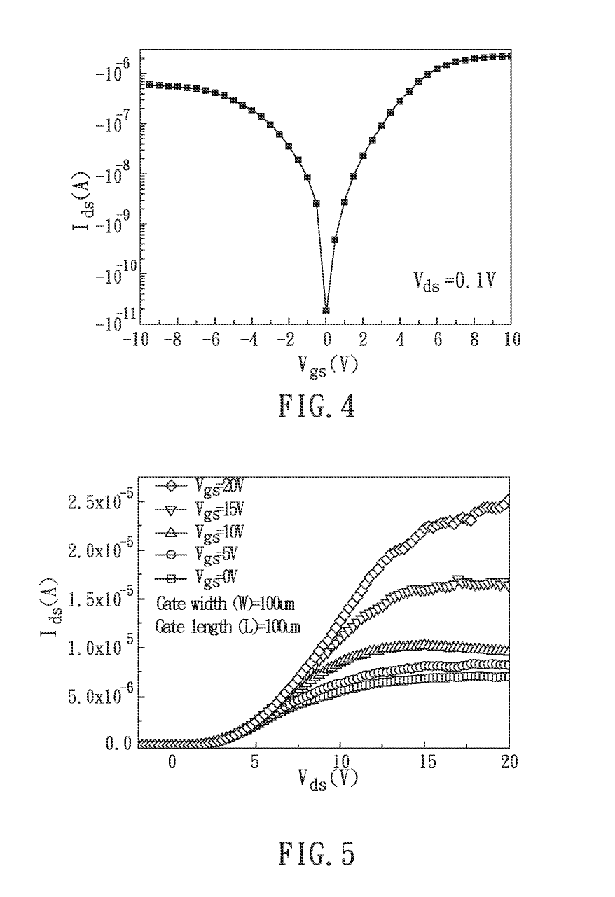

As shown in FIG. 4 and FIG. 5, wherein one is a I_{ds}-V_{gs} curve for a single-walled carbon nanotube transistor with W=100 μm, L=20 μm, and the other is the same but under n-type operation. From the formula μ_{eff}=(dI_{ds}/dV_{gs})(Ltₒₓ/∈WV_{ds}), the field effect mobility of the transistor can be calculated, wherein dI_{ds}/dV_{gs} is the transconductance, L and W each represents the length and width of the passage channel, tₒₓ is the thickness of the passage channel thin film, ∈ is the dielectric constant of the oxide gate layer, V_{gs} is the applied voltage from the drain electrode-source electrode.

It can be seen from FIG. 4 that the property of the thin film transistor as produced from the carbon nanotube thin film without an annealing treatment is ambipolar. When used as a p-type passage channel for transporting, a measurement for the electron hole carrier reveals a Vₐₛ=0.1V, and its transconductance is about 3.2 μS, the on-off current ratio is approximately close to 10⁵, and the calculated field-effect carrier mobility is about 52.74 cm²/Vs. Otherwise, when used as a n-type passage channel for electro-transporting, the transconductance is about 4.3 μS, the on-off current ratio is about 10⁵, and the field-effect carrier mobility is approximately 67.08 cm²/Vs.

The present invention involves using nitrogen and oxygen annealing to conduct annealing treatment after forming oxide gate electrode on the surface of single-walled carbon nanotube, wherein the ambiduality of the singled-walled nanotube is converted to single-polarity by adjusting annealing parameters for use as a transistor part. More specifically, an advantage suggested by the present invention is realized by first covering an oxide gate electrode (for example, HfOₓ), followed by an annealing treatment, which altogether aims firstly to increase dielectric constant of the oxide gate electrode, while secondly to allow nitrogen or oxygen gas to diffuse through the oxide gate electrode to reach the nanotube during the annealing treatment.

The setup to allow direct entry of nitrogen and oxygen gas into carbon nanotube thin film as suggested by some prior arts has been known to cause the property of device parts to decrease and drop in G/D ratio, which therefore disables making of thin film transistor to have desirable property for its parts. Conversely, the present invention can not only maintain a G/D ratio value of a carbon nanotube, but also enhances its parts' property (examples include transconductance, on-off current ratio, field-effect carrier mobility etc.), this feature is not possible with the known prior arts.

While the embodiments of the invention disclosed herein are presently considered to be preferred, various changes and modifications can be made without departing from the spirit and scope of the invention. The scope of the invention is indicated in the appended claims, and all changes that come within the meaning and range of equivalents are intended to be embraced therein.

### LIST OF REFERENCE NUMERALS

1 Top gate thin film transistor
11 Silicon substrate
12 Silicon dioxide layer
13 Single-walled carbon nanotube layer
14 Drain electrode
15 Source electrode
16 Hafnium oxide layer
17 Gate electrode

What is claimed is:

1. A method for fabricating thin film transistor, the method comprising:
(A) providing a substrate;
(B) forming a source electrode, a drain electrode, and a single-walled carbon nanotube layer, wherein the source electrode and the drain electrode are disposed separately from each other, and the single-walled carbon nanotube layer is inserted between the source electrode and the drain electrode;
(C) forming an oxide gate electrode on a surface of the single-walled carbon nanotube layer;
(D) annealing a surface of the oxide gate electrode with an element selected from oxygen and nitrogen on a temperature at between about 500° C. and about 600° C.; and
(E) forming a gate electrode on the surface of the oxide gate electrode;

2. The method according to claim 1, wherein the oxide gate electrode comprises hafnium oxide (HfOₓ).

3. The method according to claim 1, wherein in step (C), the thickness of the oxide gate electrode is of between about 5 nm and about 30 nm.

4. The method according to claim 1, wherein in step (D), the duration for oxygen annealing or nitrogen annealing is between about 30 minutes to about 1 hour.

5. The method according to claim 1, wherein in step (D), the gas flow rate of for the oxygen annealing or nitrogen annealing is between about 100 sccm and 500 sccm.

6. The method according to claim 1, wherein in step (B), the single-walled carbon nanotube layer is made by the steps of:
(B1) placing a plurality of metal-containing nanoparticles into a solvent so as to form a catalyst;
(B2) immersing the substrate as prepared in step (A) in the catalyst;
(B3) removing the immersed substrate from the catalyst and entering the substrate to a calcinating treatment; and
(B4) heating the calcinated substrate, and also providing an alcohol-based growth gas source, thereby forming a plurality of single-walled carbon nanotubes on a surface of the substrate with the alcohol-based growth gas source, wherein the plurality of single-walled carbon nanotubes cross-link with each other to form a net-like structured carbon nanotube layer.

7. The method according to claim 6, wherein in step (B4), the alcohol-based growth gas is selected from the group consisting of:
methanol, ethanol, propan-1-ol, isopropyl alcohol, n-butanol, isobutanol, pentanol, and any combination thereof.

8. The method according to claim 6, wherein in step (B1), the plurality of metal-containing nanoparticles is selected from the group consisting of cobalt, molybdenum, and any combination thereof.

9. The method according to claim 1, wherein in step (B), the single-walled carbon nanotube is made a passage channel layer.

10. The method according to claim 1, wherein in step (B), the thickness of the single-walled carbon nanotube layer is between about 100 nm and about 400 nm.

11. A top gate thin film transistor which comprises:
a substrate;
a source electrode and a drain electrode, wherein each of which is disposed separately from each other by a prescribed length over a surface of the substrate;
a single-walled carbon nanotube layer comprising a plurality of single-walled carbon nanotubes
an oxide gate electrode disposed over a surface of the single-walled carbon nanotube, and, which covers a portion of the source electrode and a portion of the drain electrode; and
a gate electrode deposited over a surface of the oxide gate electrode.

12. The top gate thin film transistor according to claim 11, wherein the oxide gate electrode is selected from the group consisting of hafnium oxide, hafnium oxynitride, and any combinations thereof.

13. The top gate thin film transistor according to claim 11, wherein the single-walled carbon nanotube, as analyzed by Raman scattering spectrum, is preferrably of between 10 and between 25

14. The top gate thin film transistor according to claim 11, wherein the single-walled carbon nanotube is made a passage channel layer.

15. The top gate thin film transistor according to claim 11, wherein the thickness of the single-walled carbon nanotube is between about 100 nm and about 400 nm.
